(19) United States
(12) Patent Application Publication
(10) Pub. No.: US 2024/0290607 A1
(43) Pub. Date: Aug. 29, 2024

(54) SUBSTRATE PROCESSING METHOD, SUBSTRATE PROCESSING SYSTEM AND COMPUTER-READABLE RECORDING MEDIUM

(71) Applicant: Tokyo Electron Limited, Tokyo (JP)

(72) Inventors: Takashi UNO, Koshi City, Kumamoto (JP); Satoshi OKAWA, Kikuchi-gun, Kumamoto (JP); Naoyuki OKAMURA, Koshi City, Kumamoto (JP); Katsufumi MATSUKI, Koshi City, Kumamoto (JP)

(21) Appl. No.: 18/573,700

(22) PCT Filed: Apr. 8, 2022
(86) PCT No.: PCT/JP2022/017405

§ 371 Date: Dec. 22, 2023

(30) Foreign Application Priority Data
Jun. 24, 2021 (JP) 2021-104590

(51) Int. Cl. H01L 21/02; H01L 21/67

(52) U.S. Cl. CPC H01L 21/02019; H01L 21/6708

(57) ABSTRACT

A substrate processing method of processing a substrate includes etching a first surface of the substrate by supplying an etching liquid containing at least hydrofluoric acid and nitric acid onto the first surface. The etching of the first surface includes determining a scan width as a distance between return points set at both ends of a reciprocating movement, and a scan speed at which an etching liquid supply is reciprocated such that a first time taken for the etching liquid supply that has passed a rotation center to pass the rotation center again after turning around at the end of the reciprocating movement becomes shorter than a second time taken for the etching liquid supplied to the rotation center to be removed to an outer peripheral portion of the substrate by a centrifugal force; and etching the first surface with the determined scan width and the determined scan speed.

### TECHNICAL FIELD

The various aspects and embodiments described herein pertain generally to a substrate processing method and a substrate processing system.

### BACKGROUND

Patent Document 1 discloses a manufacturing method for a semiconductor wafer, including a process of flattening at least a surface of a wafer obtained by slicing a semiconductor ingot, and a process of etching the surface of the flattened wafer by spin etching.

### PRIOR ART DOCUMENT

Patent Document 1: Japanese Patent Laid-open Publication No. H11-135464

### DISCLOSURE OF THE INVENTION

### Problems to be Solved BY THE Invention

Exemplary embodiments provide a technique capable of appropriately controlling a surface shape of a substrate after being subjected to an etching processing.

### Means for Solving The Problems

In an exemplary embodiment, a substrate processing method of processing a substrate includes thinning a first surface of the substrate; and etching the first surface by supplying an etching liquid containing at least hydrofluoric acid and nitric acid onto the first surface while rotating the substrate after being thinned and performing a reciprocating movement of an etching liquid supply above the first surface of the substrate to pass a rotation center of the substrate. The etching of the first surface includes determining a scan width as a distance between return points set at both ends of the reciprocating movement with the rotation center therebetween, and a scan speed at which the etching liquid supply is reciprocated such that a first time taken for the etching liquid supply that has passed the rotation center to pass the rotation center again after turning around at the end of the reciprocating movement becomes shorter than a second time taken for the etching liquid supplied to the rotation center to be removed to an outer peripheral portion of the substrate by a centrifugal force caused by a rotation of the substrate; and etching the first surface with the determined scan width and the determined scan speed.

### Effect of the Invention

According to the exemplary embodiment, it is possible to appropriately control the surface shape of the substrate after being subjected to the etching processing.

### BRIEF DESCRIPTION OF THE DRAWINGS

FIG. 1 is an explanatory diagram showing an etching amount of a wafer in a conventional method.

FIG. 2 is a plan view illustrating a schematic configuration of a wafer processing system according to an exemplary embodiment.

FIG. 3 is a side view illustrating a schematic configuration of an etching apparatus.

FIG. 4 is a side view illustrating a schematic configuration of a grinding device.

FIG. 5 is a flowchart showing major processes of a wafer processing.

FIG. 6 is an explanatory diagram showing an operation in which a wafer surface is being ground by the grinding device.

FIG. 7 is an explanatory diagram showing an operation in which the wafer surface is being ground by the grinding device.

FIG. 8A to FIG. 8C are explanatory diagrams illustrating major processes of an etching processing.

FIG. 9 is a flowchart showing major processes of the etching processing according to a first exemplary embodiment.

FIG. 10 is a flowchart showing major processes of the etching processing according to a second exemplary embodiment.

FIG. 11A to FIG. 11C are explanatory diagrams showing a variation in wafer thickness in the etching processing according to the second exemplary embodiment.

FIG. 12 presents graphs showing a relationship between a rotation speed of a chuck and an etching amount.

FIG. 13 provides graphs showing a relationship between a scan rate of a nozzle and an etching amount.

FIG. 14 is an explanatory diagram illustrating a scan width of the nozzle.

FIG. 15 provides graphs showing a relationship between a scan-out position of the nozzle and an etching amount.

FIG. 16 is an explanatory diagram showing an etching amount of a wafer in a wafer processing method according to the present exemplary embodiment.

FIG. 17 is a flowchart showing major processes of a wafer processing according to another exemplary embodiment.

FIG. 18A to FIG. 18C are explanatory diagrams illustrating another application example of the technique of the present disclosure.

### DETAILED DESCRIPTION

In a manufacturing process for a semiconductor device, a cut surface of a disk-shaped silicon wafer (hereinafter, simply referred to as “wafer”) cut from a single crystalline silicon ingot with a wire saw or the like is flattened and smoothed to uniformize the thickness of the wafer. The flattening of the cut surface is performed by, for example, surface grinding or lapping. The smoothing of the cut surface is performed by, for example, spin etching of supplying an etching liquid from above the cut surface of the wafer while rotating the wafer.

It is described in the aforementioned Patent Document 1 that at least a surface of a wafer obtained by slicing a semiconductor ingot is flattened by the surface grinding or lapping and is then etched by the spin etching. In the spin etching process described in Patent Document 1, the spin etching is performed by supplying an etching liquid to the wafer while moving a discharge nozzle above an outer peripheral portion of the wafer at the beginning of the spin etching and then fixing the discharge nozzle above a central portion of the wafer whose outer peripheral portion has been etched.

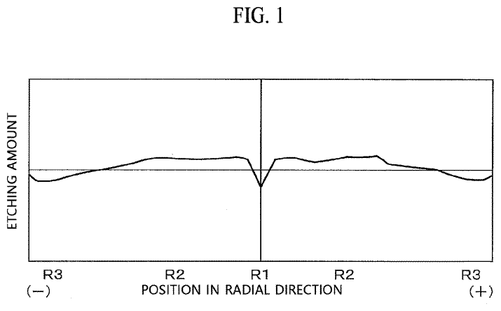

However, the inventors of the present application have found out that when the etching liquid is supplied by fixing the position of the nozzle above the central portion of the wafer according to the method described in Patent Document 1, a surface shape of the wafer after being etched cannot be appropriately controlled, especially directly below the discharge of the etching liquid. Specifically, the inventors have observed that, as shown in FIG. 1, an etching amount at a central portion R1 of the wafer directly below the discharge of the etching liquid is smaller than an etching amount at a region around the central portion R1 (hereinafter, sometimes referred to as “intermediate portion R2” as a region between the central portion R1 directly below the discharge of the etching liquid and an outer peripheral portion R3 in a radial direction). The reason for this is deemed to be as follows. While the etching proceeds at the intermediate portion R2 of the wafer to which the etching liquid supplied to the central portion R1 is flown by a centrifugal force, the supplied etching liquid (etchant) is removed by the centrifugal force at the central portion R1 directly below the discharge of the etching liquid, which makes it difficult to form a flow (a flow velocity and a flow rate of the etching liquid) required to proceed with the etching on the surface of the wafer W.

In view of the foregoing, the present disclosure provides a technique capable of appropriately controlling a surface shape of a substrate after being subjected to an etching processing. Hereinafter, a wafer processing system as a substrate processing system and a wafer processing method as a substrate processing method according to an exemplary embodiment will be described with reference to the accompanying drawings. In the present specification and the drawings, parts having substantially same functions and configurations will be assigned same reference numerals, and redundant description thereof will be omitted.

In a wafer processing system 1 according to the present exemplary embodiment, a wafer W as a substrate cut from an ingot is subjected to a processing of improving in-surface uniformity of the thickness thereof. Hereinafter, the cut surfaces of the wafer W will be respectively referred as a first surface Wa as one surface and a second surface Wb as the other surface. The first surface Wa is a surface opposite to the second surface Wb. The first surface Wa and the second surface Wb may sometimes be collectively referred to as a surface of the wafer W.

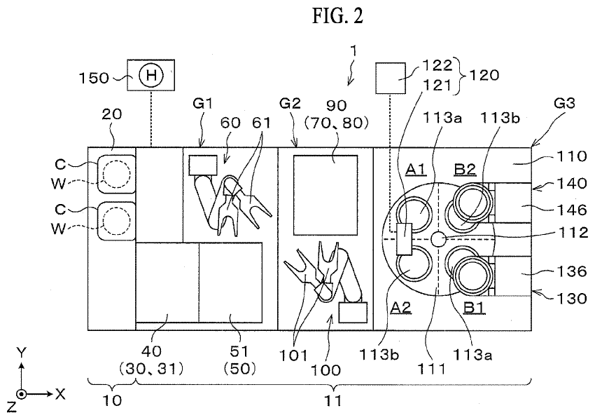

As depicted in FIG. 2, the wafer processing system 1 has a configuration in which a carry-in/out station 10 and a processing station 11 are connected as one body. In the carry-in/out station 10, a cassette C capable of accommodating therein a plurality of wafers W, for example, is carried to and from the outside. The processing station 11 is equipped with various types of processing apparatuses configured to perform required processings on the wafer W.

The carry-in/out station 10 is provided with a cassette placing table 20. In the shown example, the cassette placing table 20 is configured to place thereon a plurality of, for example, two cassettes C in a row in the Y-axis direction.

The processing station 11 is equipped with, for example, three processing blocks G1 to G3. The first processing block G1, the second processing block G2, and the third processing block G3 are arranged in this order from the negative X-axis side (carry-in/out station 10 side) to the positive X-axis side.

The first processing block G1 is equipped with inverting devices 30 and 31, a thickness measuring device 40, etching devices 50 and 51, and a wafer transfer device 60. The inverting device 30 and the etching device 50 are arranged in this order from the negative X-axis side to the positive X-axis side. The inverting devices 30 and 31 and the thickness measuring device 40 are stacked in this order from the bottom in a vertical direction, for example. The etching devices 50 and 51 are stacked in this order from the bottom in the vertical direction, for example. The wafer transfer device 60 is disposed on the positive Y-axis side of the etching devices 50 and 51. Here, the numbers and the layout of the inverting devices 30 and 31, the thickness measuring device 40, the etching devices 50 and 51, and the wafer transfer device 60 are not limited to the shown example.

The inverting devices 30 and 31 are configured to invert the first surface Wa and the second surface Wb of the wafer W in the vertical direction. The configuration of the inverting devices 30 and 31 is not particularly limited.

The thickness measuring device 40 includes, as an example, a measurement device (not shown) and a calculation device (not shown). The measurement device is equipped with a sensor configured to measure the thickness of the wafer W after being subjected to an etching processing at multiple points. The calculation device acquires a thickness distribution of the wafer W from the measurement result (thickness of the wafer W) by the measurement device, and also calculates flatness (TTV: Total Thickness Variation) of the wafer W. Here, the calculation of the thickness distribution and the flatness of the wafer W may be performed by a control device 150 to be described later, instead of the calculation device. In other words, the calculation device (not shown) may be provided in the control device 150 to be described later. Additionally, the configuration of the thickness measuring device 40 is not limited to this example, and may be modified in various ways.

The etching devices 50 and 51 etch silicon (Si) of the first surface Wa after being ground or the second surface Wb after being ground in a processing device 110 to be described later.

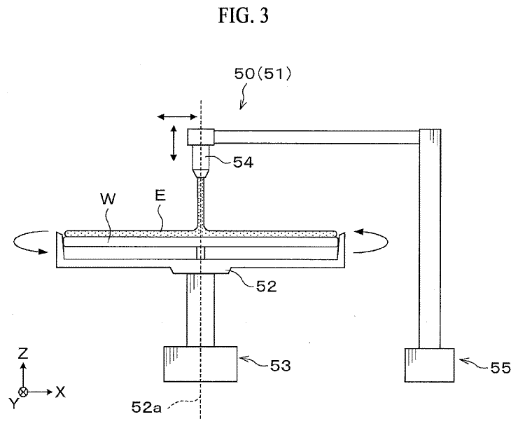

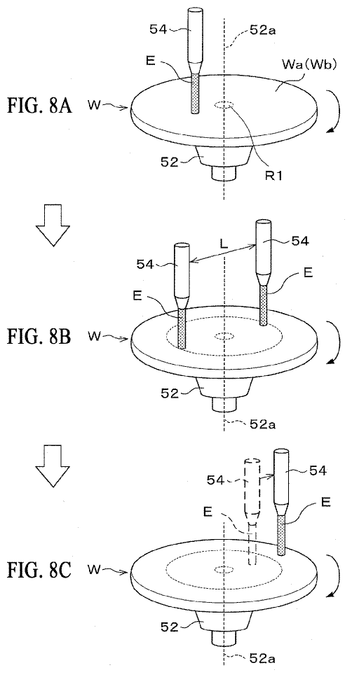

As shown in FIG. 3, each of the etching devices 50 and 51 has a holder 52, a rotating mechanism 53, and a nozzle 54 serving as an etching liquid supply. The holder 52 as a substrate holder holds an edge portion of the wafer W at multiple points, for example, at three points in the present exemplary embodiment. The configuration of the holder 52 is not limited to the shown example. By way of example, the holder 52 may be equipped with a chuck (see FIG. 8A to FIG. 8C, etc.) configured to attract and hold the wafer W from below. The rotating mechanism 53 is configured to rotate the wafer W held by the holder 52 about a vertical rotation center line 52a. The nozzle 54 is disposed above the holder 52 and is configured to be movable in a horizontal direction and a vertical direction by a moving mechanism 55. The nozzle 54 supplies an etching liquid E to the first surface Wa or the second surface Wb of the wafer W held by the holder 52.

The etching liquid E contains at least hydrofluoric acid and nitric acid in order to properly etch the silicon of the wafer W as a target of processing. As an one example, the etching liquid E is an aqueous solution containing hydrofluoric acid, nitric acid, phosphoric acid, and water, and may contain the hydrofluoric acid, the nitric acid, and the phosphoric acid at a mixing ratio of 0.5% to 40%:5% to 50%:5% to 70% by weight. Further, as an example, the etching liquid E may have a hydrofluoric acid concentration of 5% to 15% by weight and a phosphoric acid concentration of 10% to 40% by weight.

Further, the flow rate (discharge flow rate) of the etching liquid E discharged from the nozzle 54 may be in the range of, e.g., 500 mL/min to 3000 mL/min.

As illustrated in FIG. 2, the wafer transfer device 60 has, for example, two transfer arms 61 serving to hold and transfer the wafer W. Each transfer arm 61 is configured to be movable in a horizontal direction and a vertical direction and pivotable around a horizontal axis and a vertical axis. The wafer transfer device 60 is configured to transfer the wafer W to/from the cassette C of the cassette placing table 20, the inverting devices 30 and 31, the thickness measuring device 40, the etching devices 50 and 51, a buffer device 70 to be described later, a cleaning device 80 to be described later, and an inverting device 90 to be described later.

The second processing block G2 is equipped with the buffer device 70, the cleaning device 80, the inverting device 90, and the wafer transfer device 100. The buffer device 70, the cleaning device 80, and the inverting device 90 are stacked in this order from the bottom in the vertical direction, for example. The wafer transfer device 100 is disposed on the negative Y-axis side of the buffer device 70, the cleaning device 80, and the inverting device 90. Further, the numbers and the layout of the buffer device 70, the cleaning device 80, the inverting device 90, and the wafer transfer device 100 are not limited to the shown example.

The buffer device 70 is configured to temporarily hold the wafer W before being processed when it is transferred from the first processing block G1 to the second processing block G2. The configuration of the buffer device 70 is not particularly limited.

The cleaning device 80 is configured to clean the first surface Wa or the second surface Wb after being ground by the processing device 110. For example, a brush may be brought into contact with the first surface Wa or the second surface Wb to scrub-clean the first surface Wa or the second surface Wb. Further, a pressurized cleaning liquid may be used to clean the first surface Wa or the second surface Wb. In addition, the cleaning device 80 may be configured to clean the first surface Wa and the second surface Wb at the same time when cleaning the wafer W.

Like the inverting devices 30 and 31, the inverting device 90 is configured to invert the first surface Wa and the second surface Wb of the wafer W in the vertical direction. The configuration of the inverting device 90 is not particularly limited.

The wafer transfer device 100 has, for example, two transfer arms 101 serving to hold and transfer the wafer W. Each transfer arm 101 is configured to be movable in the horizontal direction and the vertical direction and pivotable around a horizontal axis and a vertical axis. The wafer transfer device 100 is configured to transfer the wafer W to/from the etching devices 50 and 51, the buffer device 70, the cleaning device 80, the inverting device 90, and the processing device 110 to be described later.

The third processing block G3 is equipped with the processing device 110. Here, the number and the layout of the processing device 110 are not limited to the shown example.

The processing device 110 has a rotary table 111. The rotary table 111 is configured to be rotatable about a vertical rotation center line 112 by a rotating mechanism (not shown). On the rotary table 111, four chucks 113 are provided to attract and hold the wafer W. Among the four chucks 113, the two first chucks 113a are used to grind the first surface Wa, and are configured to attract and hold the second surface Wb. These two first chucks 113a are positioned point-symmetrically with the rotation center line 112 therebetween. The rest two second chucks 113b are used to grind the second surface Wb, and are configured to attract and hold the first surface Wa. These two second chucks 113b are positioned point-symmetrically with the rotation center line 112 therebetween. That is, the first chucks 113a and the second chucks 113b are alternately arranged in a circumferential direction.

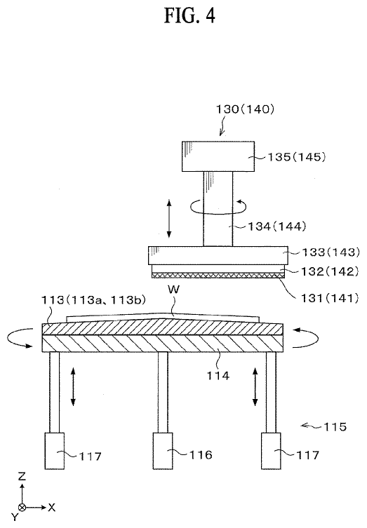

For example, a porous chuck is used as the chuck 113. A surface of the chuck 113, that is, a holding surface for the wafer W has a shape with a central portion protruding higher than an end portion when viewed from the side. Further, although the protrusion of this central portion of the chuck 113 is actually very minute, it is illustrated as being large for clarity of explanation in FIG. 4.

As depicted in FIG. 4, the chuck 113 is held on a chuck base 114. The chuck base 114 is provided with an inclination adjuster 115 configured to adjust the relative inclination between the chuck 113 and grinding whetstones 131 and 141 of grinding devices 130 and 140 to be described later. The inclination adjuster 115 has a fixed shaft 116 provided on a bottom surface of the chuck base 114 and a plurality of, for example, two elevating shafts 117. Each elevating shaft 117 is configured to be extensible and contractible and serves to move the chuck base 114 up and down. By elevating one end of an outer peripheral portion of the chuck base 114 in the vertical direction by the elevating shaft 117 with respect to the other end (the position corresponding to the fixed shaft 116) thereof by using this inclination adjuster 115, the chuck 113 and the chuck base 114 can be tilted. Thus, the relative inclination between surfaces of the grinding whetstones 131 and 141 of the grinding device 130 and 140 at processing positions B1 to B2 to be described later and the surface of the chuck 113 can be adjusted.

As shown in FIG. 2, the four chucks 113 can be moved to delivery positions A1 and A2 and the processing positions B1 and B2 as the rotary table 111 is rotated. Further, each of the four chucks 113 is configured to be rotatable around a vertical axis by a rotating mechanism (not shown).

The first delivery position A1 is a position on the negative X-axis and positive Y-axis side of the rotary table 111, where the wafer W is delivered onto the first chuck 113a when grinding the first surface Wa. The second delivery position A2 is a position on the negative X-axis and negative Y-axis side of the rotary table 111, where the wafer W is delivered onto the second chuck 113b when grinding the second surface Wb.

Disposed at the delivery positions A1 and A2 is a thickness measurer 120 which is configured to measure the thickness of the wafer W after being ground. As an example, the thickness measurer 120 includes a measurement device 121 and a calculation device 122. The measurement device 121 is equipped with a non-contact type sensor (not shown) that measures the thickness of the wafer W at multiple points. The calculation device 122 acquires a thickness distribution of the wafer W from the measurement result (thickness of the wafer W) obtained by the measurement device 121, and calculates flatness of the wafer W. In addition, the calculation of the thickness distribution and the flatness of the wafer W may be performed by the control device 150 to be described later, instead of the calculation device 122. In other words, a calculation device (not shown) may be provided in the control device 150 to be described later.

Further, although the present exemplary embodiment is described for the example where the thickness measurer 120 configured to measure the thickness of the wafer W after being subjected to a grinding processing is provided at the delivery positions A1 and A2 as illustrated in FIG. 2, the position of the thickness measurer 120 is not limited thereto. Specifically, the thickness measurer 120 may be provided at the processing positions B1 and B2 instead of the delivery positions A1 and A2, for example. As another example, the thickness measurer 120 may be stacked on the cleaning device 80 and the inverting device 90 in the second processing block G2. In this case, the wafer transfer device 100 may be configured to transfer the wafer W after being subjected to the grinding processing to the thickness measurer 120 disposed in the second processing block G2.

The first processing position B1 is a position on the positive X-axis and negative Y-axis side of the rotary table 111, and the first grinding device 130 is disposed thereat. The first grinding device 130 grinds the first surface Wa of the wafer W held by the first chuck 113a. The second processing position B2 is a position on the positive X-axis and positive Y-axis side of the rotary table 111, and the second grinding device 140 is disposed thereat. The second grinding device 140 grinds the second surface Wb of the wafer W held by the second chuck 113b.

As illustrated in FIG. 4, the first grinding device 130 includes a grinding wheel 132 having the grinding whetstone 131 of an annular shape on a bottom surface thereof; a mount 133 supporting the grinding wheel 132, a spindle 134 configured to rotate the grinding wheel 132 with the mount 133 therebetween, and a driver 135 having, for example, a motor (not shown) embedded therein. Further, the first grinding device 130 is configured to be movable in the vertical direction along a supporting column 136 shown in FIG. 2.

The second grinding device 140 has the same configuration as the first grinding device 130. That is, the second grinding device 140 has a grinding wheel 142 equipped with the grinding whetstone 141 of an annular shape, a mount 143, a spindle 144, a driver 145, and a supporting column 146.

The above-described wafer processing system 1 is provided with the control device 150 as shown in FIG. 2. The control device 150 is, by way of example, a computer equipped with a CPU, a memory, and the like, and has a program storage (not shown). The program storage stores therein a program for controlling a processing of the wafer W in the wafer processing system 1. Further, as mentioned above, the control device 150 may further include the calculation device (not shown) configured to acquire the thickness distribution of the wafer W from the measurement results (thicknesses of the wafer W) of the thickness measuring device 40 and the thickness measurer 120 and, also, configured to calculate the flatness of the wafer W. Additionally, the program may have been recorded on a computer-readable recording medium H, and may be installed from the recording medium H into the control device 150. The recording medium H may be transitory or non-transitory.

Now, a wafer processing according to a first exemplary embodiment performed by using the wafer processing system 1 configured as described above will be explained. In the present exemplary embodiment, the wafer W, on which lapping is performed after being cut out from an ingot with a wire saw or the like, is subjected to a processing of improving in-surface uniformity of the thickness thereof.

First, the cassette C accommodating therein the plurality of wafers W is placed on the cassette placing table 20 of the carry-in/out station 10. In the cassette C, the wafer W is accommodated with the first surface Wa facing upwards and the second surface Wb facing downwards. Then, the wafer W in the cassette C is taken out by the wafer transfer device 60 and transferred to the buffer device 70.

Thereafter, the wafer W is transferred to the processing device 110 by the wafer transfer device 100, and delivered to the first chuck 113a at the first delivery position A1. Here, the second surface Wb of the wafer W is attracted to and held on the first chuck 113a.

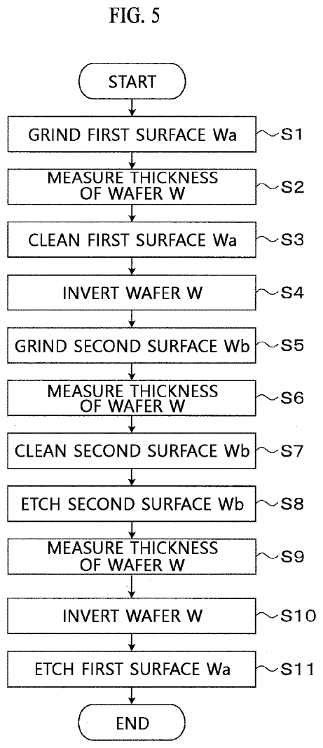

Next, the rotary table 111 is rotated to move the wafer W to the first processing position B1. Then, the first surface Wa of the wafer W is ground by the first grinding device 130 (process S1 in FIG. 5).

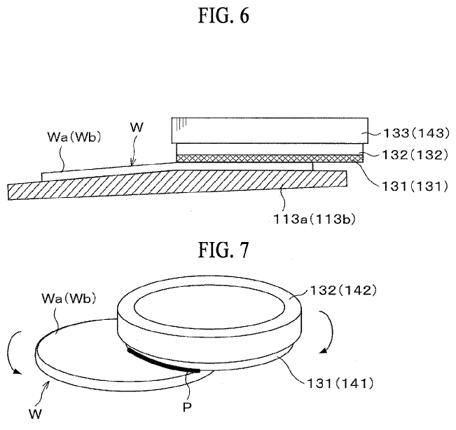

Here, the first chuck 113a has the protruding shape at the center of the holding surface of the wafer W as stated above. For this reason, when grinding the first surface Wa by using the first grinding device 130 in the process S1, the first chuck 113a is tilted such that the first surface Wa of the wafer W held by the first chuck 113a and a surface of the grinding whetstone 131 are parallel to each other as shown in FIG. 6. Further, as indicated by a thick line of FIG. 7, a portion of the annular grinding whetstone 131 comes into contact with the wafer W as a processing point P. More specifically, the annular grinding whetstone 131 and a portion of the wafer W ranging from a center to an outer end thereof come into contact with each other in an arc shape. In this state, by rotating the first chuck 113a and the grinding wheel 132, the entire first surface Wa is ground.

Subsequently, the rotary table 111 is rotated to move the wafer W to the first delivery position A1. At the first delivery position A1, the first surface Wa of the wafer W after being ground may be cleaned by a cleaning device (not shown).

Further, at the delivery position A1, the thickness of the wafer W after being subjected to the grinding processing by the first grinding device 130 is measured by the thickness measurer 120 (process S2 in FIG. 5).

Here, as described above, the thickness measurer 120 measures the thickness of the wafer W after being ground at multiple points to obtain the thickness distribution of the wafer W whose first surface Wa has been ground, and also calculates the flatness of the wafer W. The calculated thickness distribution and flatness of the wafer W (one substrate) may be outputted to, for example, the control device 150 to be used for the grinding processing of another wafer W (another substrate) to be held by the first chuck 113a (to be ground by the first grinding device 130) next. Specifically, based on the acquired thickness distribution and flatness of the wafer W (one substrate), the relative inclination between the surface of the grinding whetstone 131 and the surface of the first chuck 113a when grinding the next wafer W (another substrate) is adjusted by the inclination adjuster 115 to improve the thickness distribution and the flatness of the next wafer W (another substrate) after being ground by the first grinding device 130.

Next, the wafer W is transferred to the cleaning device 80 by the wafer transfer device 100. In the cleaning device 80, the first surface Wa of the wafer W is cleaned (process S3 in FIG. 5).

Then, the wafer W is transferred to the inverting device 90 by the wafer transfer device 100. In the inverting device 90, the first surface Wa and the second surface Wb of the wafer W are inverted in the vertical direction (process S4 in FIG. 5). That is, the wafer W is inverted with the first surface Wa facing downwards and the second surface Wb facing upwards.

Subsequently, the wafer W is transferred to the processing device 110 by the wafer transfer device 100, and delivered to the second chuck 113b at the second delivery position A2. Here, the first surface Wa of the wafer W is attracted to and held by the second chuck 113b.

Thereafter, the rotary table 111 is rotated to move the wafer W to the second processing position B2. Then, the second surface Wb of the wafer W is ground by the second grinding device 140 (process S5 in FIG. 5). Here, the method of grinding the second surface Wb of the wafer W is the same as the method of grinding the first surface Wa (process S1) shown in FIG. 6 and FIG. 7.

Next, the rotary table 111 is rotated to move the wafer W to the second delivery position A2. At the second delivery position A2, the second surface Wb of the wafer W after being ground may be cleaned by a cleaning device (not shown).

Further, at the delivery position A2, the thickness of the wafer W after being subjected to the grinding processing by the second grinding device 140 is measured by the thickness measurer 120 (process S6 in FIG. 5).

Here, as described above, the thickness measurer 120 measures the thickness of the wafer W after being ground at multiple points to obtain the thickness distribution of the wafer W whose second surface Wb has been ground, and also calculates the flatness of the wafer W. The calculated thickness distribution and flatness of the wafer W (one substrate) may be outputted to, for example, the control device 150 to be used for the grinding processing of another wafer W (another substrate) to be held by the second chuck 113b (to be ground by the second grinding device 140) next. Specifically, based on the acquired thickness distribution and flatness of the wafer W (one substrate), the relative inclination between the surface of the grinding whetstone 141 and the surface of the second chuck 113b when grinding the next wafer W (another substrate) is adjusted by the inclination adjuster 115 to improve the thickness distribution and the flatness of the next wafer W (another substrate) after being ground by the second grinding device 140.

In addition, the thickness distribution and the flatness of the wafer W acquired by the thickness measurer 120 are used in the etching processing for the second surface Wb in the etching device 51, which will be described later. Specifically, the thickness distribution and the flatness (actual surface shape of the wafer W) of the wafer W obtained after the wafer W is ground are compared with required thickness distribution and flatness (target surface shape) of the wafer W, and based on this comparison result, etching amounts of individual regions (the central portion R1, the intermediate portion R2, and the outer peripheral portion R3 shown in FIG. 1) of the wafer W in the etching device 51 are calculated. Then, various etching conditions in the etching device 51 are determined by the control device 150 such that the etching amount in each region of the wafer W becomes the calculated value. As an example, the etching conditions determined here may include a wafer rotation number to be described later, a scan width L to be described later, a scan speed to be described later, and a scan-out position to be described later.

Next, the wafer W is transferred to the cleaning device 80 by the wafer transfer device 100. In the cleaning device 80, the second surface Wb of the wafer W is cleaned (process S7 in FIG. 5).

Then, the wafer W is transferred to the etching device 51 by the wafer transfer device 60. In the etching device 51, while rotating the wafer W in the state that the wafer W is held by the holder 52 with the second surface Wb thereof facing upwards (toward the nozzle 54 side), the etching liquid E is supplied onto the second surface Wb from the nozzle 54 to thereby etch the second surface Wb (process S8 in FIG. 5).

A detailed etching method for the second surface Wb in the process S8 will be discussed.

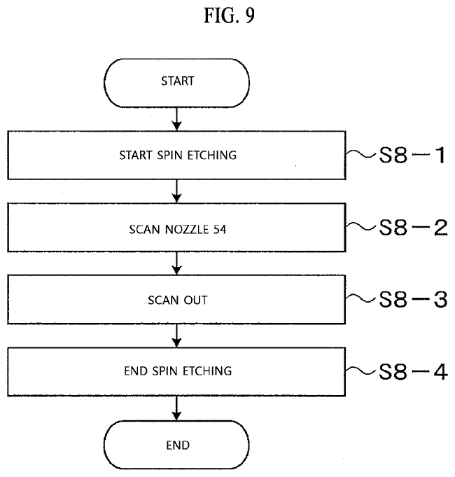

First, in the etching of the second surface Wb, the holder 52 (wafer W) is rotated about the vertical rotation center line 52a, as shown in FIG. 8A, and the discharge of the etching liquid E from the nozzle 54 is started and the spin etching of the second surface Wb is begun (process S8-1 in FIG. 9).

In the spin etching of the second surface Wb, while carrying on the discharge of the etching liquid E from the nozzle 54, the nozzle 54 is reciprocated (scanned) to pass a rotation center (central portion R1) of the wafer W, that is, the rotation center line 52a, with the rotation center line 52a as a middle point (process S8-2 in FIG. 9). Details of the scan width L of the nozzle 54 and the scan speed when reciprocating the nozzle 54 will be described later.

As illustrated in FIG. 1, when the spin etching is performed by a conventional method in which the nozzle 54 is not scanned, the etching amount at the central portion R1 of the wafer W becomes small. This is deemed to be because, as described above, the etching liquid (etchant) supplied to the central portion R1 is removed by the centrifugal force, and a flow (a flow velocity and a flow rate of the etching liquid E) required to proceed with the etching on the surface of the wafer W cannot be formed due to the removal of the etching liquid E by the centrifugal force.

As a resolution, in the spin etching according to the present exemplary embodiment, as shown in FIG. 8B, while carrying on the discharge of the etching liquid E from the nozzle 54, the nozzle 54 is reciprocated (scanned) to pass the rotation center (central portion R1) of the wafer W, that is, the rotation center line 52a, with the rotation center line 52a as the middle point. As a result, while supplying the etching liquid E to the central portion R1 of the wafer W, the flow of the etching liquid E is generated on the surface of the wafer W in the central portion R1, so that the etching can be carried out appropriately.

If a required etching amount is obtained for the wafer W, the nozzle 54 is then moved to a scan-out position (a discharge end position of the etching liquid E) as shown in FIG. 8C, while carrying on the discharge of the etching liquid E from the nozzle 54 (process S8-3 in FIG. 9). Details of the scan-out position (the discharge end position of the etching liquid E) of the nozzle 54 will be described later.

If the nozzle 54 is moved to the scan-out position, the discharge of the etching liquid E from the nozzle 54 and the rotation of the holder 52 (wafer W) are stopped, and the spin etching of the second surface Wb is ended (process S8-4 in FIG. 9).

Here, as stated above, the etching conditions for the second surface Wb in the process S8 are determined based on the thickness distribution and the flatness of the wafer W after being subjected to the grinding of the second surface Wb, which are obtained in the process S6. To elaborate, based on the thickness distribution obtained in the process S6, the etching conditions are decided such that the etching amount is large at a portion where the thickness is found to be large, whereas the etching amount is small at a portion where the thickness is found to be small. Details of the etching conditions will be described later.

Reference is made back to FIG. 5.

Upon the completion of the etching of the second surface Wb of the wafer W, the second surface Wb after being etched is rinsed by pure water and dried in the same etching device 51. Once the second surface Wb is dried, the wafer W is then transferred to the thickness measuring device 40 by the wafer transfer device 60. The thickness measuring device 40 measures the thickness of the wafer W after being etched by the etching device 51 (process S9 in FIG. 5).

Here, as described above, the thickness measuring device 40 measures the thickness of the wafer W at the multiple points to obtain the thickness distribution of the wafer W after being subjected to the etching of the second surface Wb, and also calculates the flatness of the wafer W. The thickness distribution and the flatness of the wafer W thus calculated are outputted to, for example, the control device 150, and are used for the etching processing of the first surface Wa of the wafer W in the etching device 50. Specifically, based on the acquired thickness distribution and flatness of the wafer W, or based only on the acquired thickness distribution of the wafer W, a target etching amount of silicon of the wafer W in the etching device 50 is calculated, and the etching conditions in the etching device 50 are determined so as to obtain the target etching amount.

Next, the wafer W is transferred to the inverting device 31 by the wafer transfer device 60. In the inverting device 31, the first surface Wa and the second surface Wb of the wafer W are inverted in the vertical direction (process S10 in FIG. 5). That is, the wafer W is inverted with the first surface Wa facing upwards and the second surface Wb facing downwards.

Subsequently, the wafer W is transferred to the etching device 50 by the wafer transfer device 60. In the etching device 50, the wafer W is held by the holder 52 with the first surface Wa thereof facing upwards. Then, while rotating the wafer W in this state, the etching liquid E is supplied from the nozzle 54 to the first surface Wa to etch the first surface Wa (process S11 in FIG. 5). This etching processing (process S11) of the first surface Wa is performed by the same method as the etching processing (process S8) of the second surface Wb shown in FIG. 8A to FIG. 8C and FIG. 9, for example. At this time, the etching conditions for the first surface Wa are determined based on the thickness distribution and the flatness of the wafer W after being subjected to the etching of the second surface Wb obtained in the process S9 as described above, or based only on the thickness distribution of the wafer W.

That is, in the wafer W after being subjected to the etching processing of the first surface Wa, both the flatness and the in-surface uniformity of the thickness distribution may be improved, or only the in-surface uniformity of the thickness distribution may be improved, ignoring the flatness (target shape).

Upon the completion of the etching of the first surface Wa, all the processings for the wafer W in the wafer processing system 1 are completed, so the wafer W is transferred to the cassette C on the cassette placing table 20 by the wafer transfer device 60. In this way, the series of processes of the wafer processing in the wafer processing system 1 are ended. Additionally, at the outside of the wafer processing system 1, polishing may be performed on the wafer W after being subjected to the required processing in the wafer processing system 1.

Further, although the wafer W after being subjected to the etching of the first surface Wa in the etching device 50 is transferred to the cassette C of the cassette placing table 20 by the wafer transfer device 60 in the above-described exemplary embodiment, the measurement of the thickness (calculation of the thickness distribution and the flatness) of the wafer W after being subjected to the etching of the first surface Wa may be performed before the wafer W is transferred to the cassette C. The thickness of the wafer W after being subjected to the etching of the first surface Wa may be measured by, for example, the thickness measuring device 40. The measured thickness of the wafer W is outputted to, for example, the control device 150 to be used in the etching processing of the wafer W (another substrate) to be processed next in the wafer processing system 1.

Now, details of the etching conditions for the second surface Wb in the process S8 and the etching conditions for the first surface Wa in the process S10 will be explained. Hereinafter, effects of the wafer rotation number, the scan speed, the scan width L, and the scan-out position as the etching conditions will be explained. Additionally, in order to investigate the effects of the various etching conditions, the inventors of the present application have conducted various examinations as follows, using a wafer W having a diameter of 300 mm as an example.

### <Wafer Rotation Number>

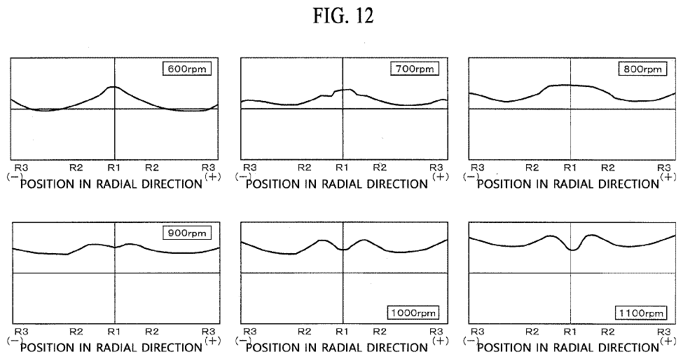

First, the inventors of the present application have measured an in-surface etching amount distribution of the wafer W while varying, as an etching condition for the wafer W, the rotation number of the holder 52 (wafer W) in the process S8 to 600 rpm, 700 rpm, 800 rpm, 900 rpm, 1000 rpm, and 1100 rpm. In FIG. 12, a horizontal axis of each graph represents a position of the wafer W in a radial position, and a vertical axis represents an etching amount. In this measurement, conditions other than the rotation number of the holder 52 (wafer W) are identical.

As shown in FIG. 12, when the rotation number of the wafer W is 600 rpm, the etching amount distribution is found to have a convex shape with a large etching amount at the central portion R1. On the other hand, as the rotation number of the wafer W increases to approach 900 rpm, the etching amount distribution is found to have improved flatness so the etching amount of the wafer W becomes approximately uniform over the entire surface thereof. Further, it is also found out that, by increasing the rotation number of the wafer W, the etching amount distribution becomes a concave shape with a small etching amount at the central portion R1.

Further, at this time, the etching amount of the central portion R1 (vertical axis position at the central portion R1 in FIG. 12) is found to be approximately constant regardless of the rotation number of the wafer W, and the surface shape of the wafer W is flattened as the etching amounts at the intermediate portion R2 and the outer peripheral portion R3 are changed.

This is deemed to be because, at the central portion R1 including the rotation center of the wafer W, the supplied etching liquid E is removed toward the outer peripheral portion R3 by the centrifugal force regardless of the rotation number of the wafer W, and the flow (flow rate and flow velocity) of the etching liquid E on the surface of the wafer W at the central portion R1 becomes approximately constant.

In addition, at the intermediate portion R2 and the outer peripheral portion R3, which are the regions radially outside the central portion R1, it is conjectured that the flow (flow rate and flow velocity) of the etching liquid E flown from the central portion R1 side by the centrifugal force varies according to the rotation number of the wafer W, resulting in the change in the etching amount.

As described above, by controlling the rotation number of the holder 52 (wafer W) in the process S8, the etching amount at the intermediate portion R2 and the outer peripheral portion R3 of the wafer W in particular can be adjusted, so that the surface shape of the wafer W after being etched can be controlled.

At this time, it is desirable that the rotation number of the holder 52 (wafer W) is determined by referring to the thickness distribution and the flatness of the wafer W measured in the process S6 and the process S9 of FIG. 5, respectively, such that a difference between the thickness of the wafer W at the central portion R1 and the thickness of the wafer W at the outer peripheral portion R3 is reduced.

Further, in one exemplary embodiment, it is desirable that the rotation number of the holder 52 (wafer W) is determined such that a time (first time) taken for the nozzle 54 that has passed the rotation center line 52a (central portion R1) to pass the rotation center line 52a (central portion R1) again after turning around at an end of the reciprocating movement becomes shorter than a time (second time) taken for the etching liquid E supplied to the rotation center line 52a (central portion R1) to be removed to the outer peripheral portion R3 of the wafer W due to the centrifugal force accompanying the rotation of the holder 52 (wafer W) (first time<second time). The determined rotation number is set in the control device 150, for example.

Theses etching amounts are deemed to vary depending on, for example, a supply flow rate and viscosity of the etching liquid E as well. In particular, the appropriate rotation number of the holder 52 (wafer W) in the present exemplary embodiment is 800 rpm to 1000 rpm, desirably 850 rpm to 950 rpm, and more desirably 900 rpm.

### <Scan Speed>

Next, the inventors of the present application have investigated the scan speed of the nozzle 54 in the process S8-2 as the etching condition for the wafer W.

In the process S8-2, in order to allow the etching at the central portion R1 to continue to proceed, it is desirable to determine the scan speed of the nozzle 54 such that the central portion R1 is not dried out due to the centrifugal force. The etching liquid E supplied to the central portion R1 is removed toward the outer peripheral portion R3 by the centrifugal force. However, it is desirable that the scan speed is determined to allow the nozzle 54 to be moved to above the central portion R1 again to replenish the etching liquid E before the supplied etching liquid E is completely removed from the central portion R1.

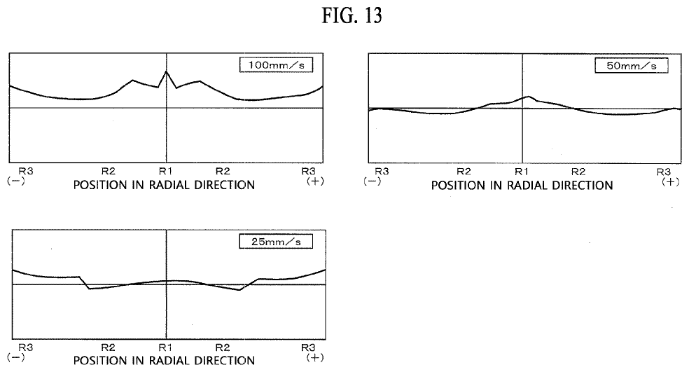

Therefore, the inventors of the present application have measured the in-surface etching amount distribution of the wafer W while varying the scan speed of the nozzle 54 in the process S8-2 to 100 mm/s, 50 mm/s, and 25 mm/s as the etching condition for the wafer W. In FIG. 13, a horizontal axis of each graph represents a position of the wafer W in the radial direction, and a vertical axis represents an etching amount. In addition, in this measurement, conditions other than the scan speed of the nozzle 54 are constant. Further, in this measurement, the nozzle 54 is reciprocated (scanned) above the wafer W with the central portion R1 (rotation center line 52a) of the wafer W as the middle point of the reciprocating movement. At this time, a distance between return points corresponding to both ends of the reciprocating movement, that is, the scan width L of the reciprocating movement of the nozzle 54 is also set to be same.

As can be seen from FIG. 13, when the scan speed of the nozzle 54 is 100 mm/s, the etching amount distribution is found to be of a convex shape in which the etching amount of the central portion R1 is larger. On the other hand, it is also found out that by lowering the scan speed of the nozzle 54, the etching amount of the central portion R1 is reduced. When the scan speed is 25 mm/s, the convex shape of the central portion R1 disappears, and the flatness of the wafer W is found to be improved.

At this time, it is also observed that the etching amount of the central portion R1 decreases as the scan speed of the nozzle 54 is lowered.

This is deemed to be because the faster the scan speed of the nozzle 54 is, the shorter the time taken for the nozzle 54 to return to above the central portion R1 through the reciprocating movement may become, resulting in an increase of the frequency of the supply of the etching liquid E to the central portion R1.

As stated above, by controlling the scan speed of the nozzle 54 in the process S8-2, the etching amount at the central portion R1 of the wafer W in particular can be adjusted. In one exemplary embodiment, it is desirable that the scan speed of the nozzle 54 is determined such that the time (first time) taken for the nozzle 54 that has passed the rotation center line 52a (central portion R1) to pass the rotation center line 52a (central portion R1) again after turning around at the end of the reciprocating movement becomes shorter than the time (second time) taken for the etching liquid E supplied to the rotation center line 52a (central portion R1) to be removed to the outer peripheral portion R3 of the wafer W due to the centrifugal force accompanying the rotation of the holder 52 (wafer W) (first time<second time). The determined scan speed is set in the control device 150, for example.

The appropriate scan speed of the nozzle 54 in the present exemplary embodiment is, for example, 25 mm/s, as shown in FIG. 13 as well.

Additionally, the etching amount at the central portion R1 of the wafer W also varies depending on the scan width L of the nozzle 54, which will be described later. For this reason, it is desirable to control the scan speed of the nozzle 54 and the scan width L of the nozzle 54 together. This enables the central portion R1 of the wafer W to be more appropriately suppressed from being dried out due to the centrifugal force.

### <Scan Width L>

Next, the inventors of the present application have examined the scan width L of the nozzle 54 in the process S8-2 (see FIG. 8B) as the etching condition for the wafer W. Here, the scan width L of the nozzle 54 is, as described above, the distance between the return points at both ends of the reciprocating movement of the nozzle 54.

As described above, in the process S8-2, it is desirable that the scan width L of the nozzle 54 is determined such that the central portion R1 is not dried out due to the centrifugal force to thereby allow the etching at the central portion R1 to continue to proceed. The etching liquid E supplied to the central portion R1 is removed toward the outer peripheral portion R3 by the centrifugal force. However, it is desirable that the scan width L is determined to allow the nozzle 54 to be moved to above the central portion R1 again to replenish the etching liquid E before the supplied etching liquid E is completely removed from the central portion R1. To elaborate, by reducing the scan width L of the nozzle 54, the time required for the nozzle 54 to return to above the central portion R1 decreases, and by increasing the scan width L, the time required for the nozzle 54 to return to above the central portion R1 increases.

As described above, by controlling the scan width L of the nozzle 54 in the process S8-2, the etching amount at the central portion R1 of the wafer W in particular can be adjusted.

In one exemplary embodiment, it is desirable that the scan width L of the nozzle 54 is determined such that the time (first time) taken for the nozzle 54 that has passed the rotation center line 52a (central portion R1) to pass the rotation center line 52a (central portion R1) again after turning around at the end of the reciprocating movement becomes shorter than the time (second time) taken for the etching liquid E supplied to the rotation center line 52a (central portion R1) to be removed to the outer peripheral portion R3 of the wafer W due to the centrifugal force accompanying the rotation of the holder 52 (wafer W) (first time<second time). The determined scan width L is set in the control device 150, for example.

Furthermore, in one exemplary embodiment, a portion with a large thickness (a portion where the etching amount needs to be increased) near the central portion R1 may be specified based on the thickness distribution and the flatness of the wafer W measured in the process S6 and the process S9 of FIG. 5, respectively, and the scan width L of the nozzle 54 may be determined to correspond to the region of this portion with the large thickness.

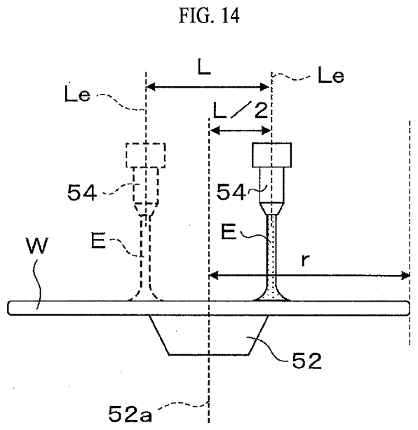

The inventors of the present application have conducted extensive studies and have found that the appropriate scan width L in the present exemplary embodiment in particular is equal to or less than a radius r of the wafer W, desirably equal to or less than ⅔r. In other words, as shown in FIG. 14, a distance L/2 from the rotation center line 52a of the wafer W to a return point Le as the end of the reciprocating movement is less than r/2, desirably less than r/3.

Additionally, the etching amount at the central portion R1 of the wafer W also varies depending on the scan speed of the nozzle 54, as described above. For this reason, it is desirable to control the scan width L of the nozzle 54 and the scan speed of the nozzle 54 together. This enables the central portion R1 of the wafer W to be more appropriately suppressed from being dried due to centrifugal force.

### <Scan-Out Position>

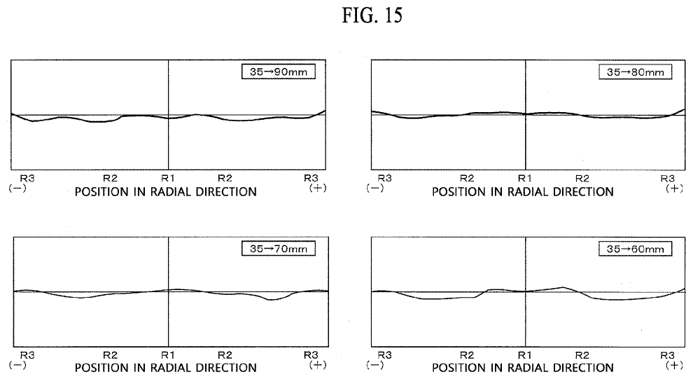

Next, the inventors of the present application have measured the in-surface etching amount distribution of the wafer W while varying the scan-out position of the nozzle 54 (discharge end position of the etching liquid E) in the process S8-3 to 90 mm, 80 mm, 70 mm, and 60 mm from the central portion R1 (rotation center line 52a) of the wafer W as an etching condition for the wafer W. In this measurement, the nozzle 54 is moved to the respective scan-out positions from a point of 35 mm from the central portion R1 (rotation center line 52a) of the wafer W serving as the return point of the reciprocating movement (end of the scan width L) in the process S8-2. In FIG. 15, a horizontal axis of each graph represents a position of the wafer W in the radial direction, and a vertical axis represents an etching amount. Further, in this measurement, conditions other than the scan-out position of the nozzle 54 are constant.

As can be seen from FIG. 15, when the scan-out position of the nozzle 54 is 60 mm from the central portion R1, the etching amount distribution is found to have an approximately W-shape with a particularly small etching amount at the intermediate portion R2. On the other hand, it is found out that by moving the scan-out position of the nozzle 54 radially outwards (towards the outer peripheral portion R3 side), the etching amount distribution has improved flatness so the etching amount of the wafer W becomes substantially uniform over the entire surface thereof.

When only the reciprocating movement of the nozzle 54 in the process S8-2 is performed, the etching amount at the central portion R1 of the wafer W may be larger than the etching amounts at the intermediate portion R2 and the outer peripheral portion R3, the same as in the prior art method. However, by moving the nozzle 54 to the scan-out position while carrying on the discharge of the etching liquid E, the etching may be further performed at the intermediate portion R2 and the outer peripheral portion R3 (outside the return point of the reciprocating movement in the process S8-2) where the etching amount decreases. This is deemed to be the reason why the etching amount distribution is given the improved flatness when the nozzle 54 is moved to the scan-out position.

As described above, by controlling the scan-out position of the nozzle 54 in the process S8-3, the etching amount at the intermediate portion R2 and the outer peripheral portion R3 of the wafer W in particular is adjusted to control the surface shape of the wafer W after being etching.

At this time, it is desirable that the scan-out position of the nozzle 54 is determined based on the thickness distribution and the flatness of the wafer W measured in the process S6 and the process S9 of FIG. 5, respectively, to correspond to the portion where the thickness of the wafer W is large, that is, a portion where the etching amount needs to be increased in a region ranging from the return point of the reciprocating movement (end of the scan width L) in the process S8-2 to the outer end of the wafer W. The determined scan-out position is set in the control device 150, for example.

The appropriate scan-out position of the nozzle 54 in the present exemplary embodiment is, for example, a position of 80 mm from the central portion R1 (rotation center line 52a) of the wafer W, as shown in FIG. 15.

Further, as illustrated in FIG. 3, when the wafer W is supported at three points on the edge thereof in the etching devices 50 and 51, if the nozzle 54 is moved to the outer end of the wafer W while discharging the etching liquid E, there is a risk that the etching liquid E supplied to the surface of the wafer W may collide with the holder 52 to be splashed back, causing the etching amount distribution of the wafer W to be disturbed. However, by ending the discharge of the etching liquid E at the scan-out position without continuing the discharge of the etching liquid E up to the outer end of the wafer W as described above, the disturbance in the etching amount distribution due to the splash-back of the etching liquid E can be suppressed.

The etching conditions for the wafer W according to the present exemplary embodiment are determined as described above. Further, the etching conditions to be determined are not limited to the aforementioned examples. By way of example, a control over a moving speed of the nozzle 54 to the scan-out position in the above-described scan-out may be performed by the control device 150.

Furthermore, as described above, it is assumed that the etching amount of the silicon in the etching device varies depending on, for example, the supply flow rate and the viscosity of the etching liquid E.

In consideration of this, a tendency of the etching amount (etching amount distribution in the surface of the wafer W) under each etching condition described above, that is, a correlation between each etching condition and the etching amount depending on the kind (viscosity and concentration) or supply flow rate of the chemical liquid may be acquired by and stored in the control device 150 in advance. Then, by determining the optimal etching conditions (rotation number, scan width, scan-out position, scan speed) based on the thickness distribution of the wafer W before being etched, which is obtained in the processes S6 and S9, the surface shape of the wafer W can be appropriately processed into the required shape.

Furthermore, in case that the surface shape of the wafer W is predicted to be deteriorated when the wafer W is processed according to a processing recipe set before the etching processing, for example, the etching conditions may be changed to obtain the required surface shape of the wafer W.

Moreover, in the above-described first exemplary embodiment, the conditions for the etching (process S8) of the second surface Wb of the wafer W are decided based on the thickness distribution of the wafer W obtained in the process S6. However, the etching of the second surface Wb may be performed under the fixed conditions (fixed recipe) in which the etching amount of the second surface Wb is uniform over the entire surface of the wafer W.

Hereinafter, a wafer processing according to a second exemplary embodiment, in which the second surface Wb is etched according to the fixed recipe, will be described. Further, in this second exemplary embodiment as well, the wafer W, on which lapping is performed after being cut out from the ingot with the wire saw or the like, is subjected to a processing of improving the in-surface uniformity of the thickness thereof. In addition, in the following description, detailed description of processes that are substantially the same as those of the wafer processing according to the first exemplary embodiment described above will be omitted.

First, the wafer W in the cassette C placed on the cassette placing table 20 is taken out by the wafer transfer device 60, and delivered onto the first chuck 113a of the processing device 110 via the buffer device 70 and the wafer transfer device 100. Here, the second surface Wb of the wafer W is attracted to and held by the first chuck 113a.

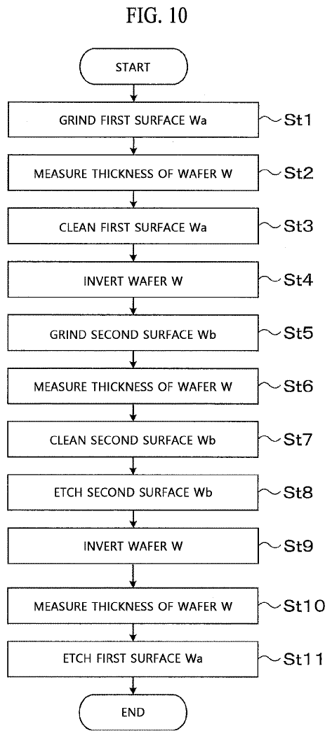

Then, the rotary table 111 is rotated to move the wafer W to the first processing position B1, and the first surface Wa of the wafer W is ground by the first grinding device 130 (process St1 in FIG. 10). The method of grinding the wafer W by the first grinding device 130 is the same as the method in the process S1 according to the first exemplary embodiment.

Subsequently, the rotary table 111 is rotated to move the wafer W to the first transfer position A1, and the thickness of the wafer W after being ground by the first grinding device 130 is measured by the thickness measurer 120 at multiple points (process St2 in FIG. 10). The thickness measurer 120 then acquires a thickness distribution from the thicknesses of the wafer W measured at the multiple points. The calculated thickness distribution of the wafer W is outputted to, for example, the control device 150 to be used in a grinding processing for another wafer W to be held by the first chuck 113a (to be ground by the first grinding device 130) next.

Next, the wafer W is transferred to the cleaning device 80 by the wafer transfer device 100. In the cleaning device 80, the first surface Wa of the wafer W is cleaned (process St3 in FIG. 10).

Thereafter, the wafer W is transferred to the inverting device 90 by the wafer transfer device 100. In the inverting device 90, the first surface Wa and the second surface Wb of the wafer W are inverted in the vertical direction (process St4 in FIG. 10). That is, the wafer W is inverted with the first surface Wa facing downwards and the second surface Wb facing upwards.

Subsequently, the wafer W is transferred to the processing device 110 by the wafer transfer device 100, and delivered onto the second chuck 113b at the second transfer position A2. Here, the first surface Wa of the wafer W is attracted to and held by the second chuck 113b.

Then, the rotary table 111 is rotated to move the wafer W to the second processing position B2, and the second surface Wb of the wafer W is ground by the second grinding device 140 (process St5 in FIG. 10). The method of grinding the wafer W by the second grinding device 140 is the same as the method (process St1) of grinding the first surface Wa.

Next, the rotary table 111 is rotated to move the wafer W to the second transfer position A2, and the thickness of the wafer W after being ground by the second grinding device 140 is measured by the thickness measurer 120 at multiple points (process St6 in FIG. 10). The thickness measurer 120 then acquires a thickness distribution from the thicknesses of the wafer W measured at the multiple points. The calculated thickness distribution of the wafer W is outputted to, for example, the control device 150 to be used in a grinding processing for another wafer W to be held by the second chuck 113b (to be ground by the second grinding device 140) next.

Further, in the first exemplary embodiment described before, the etching conditions (etching amount in the surface of the wafer W) for the second surface Wb in the etching device 51 are determined based on the thickness distribution of the wafer W obtained by the thickness measurer 120 in this way. In the present exemplary embodiment, however, this is not performed.

Once the thickness of the wafer W after being ground by the second grinding device 140 is measured, the wafer W is then transferred to the cleaning device 80 by the wafer transfer device 100. In the cleaning device 80, the second surface Wb of the wafer W is cleaned (process St7 in FIG. 10).

Then, the wafer W is transferred to the etching device 51 by the wafer transfer device 60. In the etching device 51, while rotating the wafer W in the state that the wafer W is held by the holder 52 with the second surface Wb thereof facing upwards (towards the nozzle 54), the etching liquid E is supplied to the second surface Wb from the nozzle 54 to etch the second surface Wb (process St8 in FIG. 10).

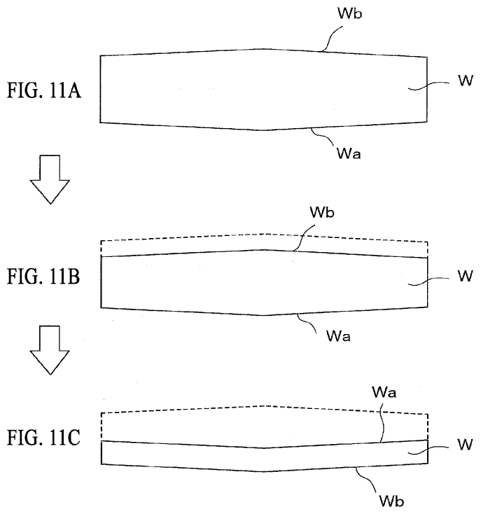

Here, in the etching of the second surface Wb according to the second exemplary embodiment, instead of determining the etching amount in the surface of the wafer W based on the thickness distribution of the wafer W as described in the first exemplary embodiment, the entire second surface Wb of the wafer W after being subjected to the grinding processing shown in FIG. 11A is etched to the same thickness as shown in FIG. 11B, using the fixed conditions (fixed recipe).

According to the second exemplary embodiment, the etching conditions for the second surface Wb are simplified as compared to the first exemplary embodiment in that the fixed conditions (fixed recipe) are used. As a result, throughput of the etching of the second surface Wb in the process S8 can be improved.

Once the required etching amount is obtained on the front surface of the second surface Wb, the discharge of the etching liquid E from the nozzle 54 and the rotation of the holder 52 (wafer W) are stopped, so that the spin etching of the second surface Wb is ended.

Upon the completion of the etching of the second surface Wb of the wafer W, the etched second surface Wb is rinsed with pure water in the same etching device 51, and the second surface Wb is then dried. After the second surface Wb is dried, the wafer W is then transferred to the inverting device 31 by the wafer transfer device 60. In the inverting device 31, the first surface Wa and the second surface Wb of the wafer W are inverted in the vertical direction (process St9 in FIG. 10). That is, the wafer W is inverted with the first surface Wa facing upwards and the second surface Wb facing downwards.

Next, the wafer W is transferred to the thickness measuring device 40 by the wafer transfer device 60, and the thickness of the wafer W after being etched by the etching device 51 is measured (process St10 in FIG. 10).

In the thickness measuring device 40, the thickness distribution of the wafer W after being subjected to the etching of the second surface Wb is acquired by measuring the thickness of the wafer W at multiple points. The calculated thickness distribution of the wafer W is outputted to, for example, the control device 150 to be used in the etching processing of the first surface Wa of the wafer W in the etching device 50. Specifically, based on the obtained thickness distribution of the wafer W, a target etching amount of the silicon of the wafer W in the etching device 50 is calculated, and the etching conditions in the etching device 50 are determined so as to achieve the calculated target etching amount.

Additionally, the etching amount of the silicon of the wafer W in the etching device 50 is determined such that the thickness of the wafer W to be etched becomes uniform in the surface thereof. Specifically, based on the calculated thickness distribution, the etching conditions are determined such that the etching amount is increased at a portion where the thickness is found to be large, whereas the etching amount is reduced at a portion where the thickness is found to be small. Further, the etching conditions to be determined include, for example, the wafer rotation number, the scan speed, the scan width L, the scan-out position, and so forth as stated above.

Next, the wafer W is transferred to the etching device 50 by the wafer transfer device 60. In the etching device 50, while rotating the wafer W in the state that the wafer W is held by the holder 52 with the first surface Wa facing upwards, the etching liquid E is supplied from the nozzle 54 onto the first surface Wa to etch the first surface Wa (process St11 in FIG. 10).

In this etching processing for the first surface Wa, the etching of the first surface Wa is performed under the condition that allows the in-surface thickness of the wafer W to become uniform, and as a result, the wafer W having the uniform thickness across the entire surface thereof is obtained as shown in FIG. 11C.

Upon the completion of the etching of the first surface Wa, all the processes on the wafer W in the wafer processing system 1 are completed, and the wafer W is transferred to the cassette C on the cassette placing table 20 by the wafer transfer device 60. In this way, the series of processes of the wafer processing in the wafer processing system 1 are ended.

As described above, in the wafer processing according to the second exemplary embodiment, while improving the throughput of the etching of the second surface Wb in the process S8, by performing the etching of the first surface Wa such that the surface shape of the second surface Wb is reflected, as described above, the in-surface uniformity of the thickness of the wafer W can be improved.

### <Effects of Technique of Present Disclosure>

According to the technique of the present disclosure, when etching the wafer W, the nozzle 54 configured to discharge the etching liquid E is reciprocated to pass the rotation center line 52a of the wafer W, so that the central portion R1 directly below the discharge of the etching liquid E can be appropriately etched. Specifically, by reciprocating the nozzle 54 in this way, the flow of the etching liquid E can be formed on the surface of the wafer W at the central portion R1, which enables the etching to proceed at the central portion R1.

In addition, according to the first exemplary embodiment, the etching conditions for the first surface Wa and the second surface Wb of the wafer W are determined based on the thickness distribution and the flatness of the wafer W measured in advance before the etching. In this case, these etching conditions can be set for the first surface Wa and the second surface Wb individually, so that the in-surface shapes of the first surface Wa and the second surface Wb can be controlled individually.

Specifically, by controlling the scan speed and the scan width L of the nozzle 54 during the etching processing, the etching amount at the central portion R1 of the wafer W can be controlled. Further, by controlling the rotation speed of the holder 52 (wafer W) and the scan-out position of the nozzle 54 during the etching processing, the control of controlling the etching amounts at the intermediate portion R2 and the outer peripheral portion R3 of the wafer W can be carried out by the control device 150.

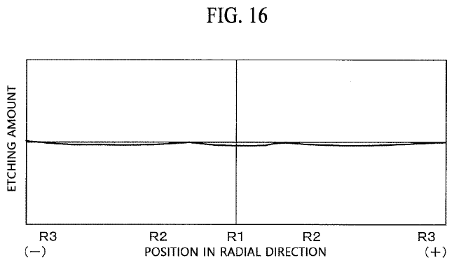

According to the present exemplary embodiment, by determining the etching conditions individually as described above, the etching amount distribution, which has conventionally been non-uniform in the surface of the wafer W as shown in FIG. 1, can be made substantially uniform in the surface of the wafer Was illustrated in FIG. 16. As a result, the flatness of the wafer W can be appropriately improved.

In addition, according to the second exemplary embodiment, after wet etching of one surface of the wafer W is performed under fixed conditions, etching conditions on the other surface are determined based on the thickness distribution of the wafer W after being subjected to the wet etching. In this case, it is possible to control the in-surface thickness of the wafer W to be uniform, while improving throughput of the etching of the one surface.

Further, the above exemplary embodiments have been described for the case of controlling the etching conditions to uniformly control the etching amount of the wafer W in the surface of the wafer W as shown in FIG. 16. However, according to the technique of the present disclosure, the surface shape of the wafer W after being subjected to the etching processing may be controlled into the required shape (for example, convex shape, concave shape, W-shape, etc.) by controlling the etching conditions according to the purpose of processing the wafer W, for example.

As described above, in the first exemplary embodiment, by controlling the etching conditions, the etching amount of the wafer W is controlled to improve the thickness distribution and the flatness of the wafer W. However, the flatness of the wafer W does not need to be improved, and only the thickness distribution of the wafer W may be improved.

In addition, in the technique of the present disclosure, prior to grinding of the first surface Wa and the second surface Wb of the wafer W (process S1 and process S5 in FIG. 5), pre-etching may be performed to reduce a processing load in the grinding of the first surface Wa and the second surface Wb. In this case, the pre-etching before grinding may be performed in one of the two etching devices 50 and 51 (for example, the etching device 50) disposed in the wafer processing system 1, and post-etching after grinding may be performed in the other (for example, the etching device 51).

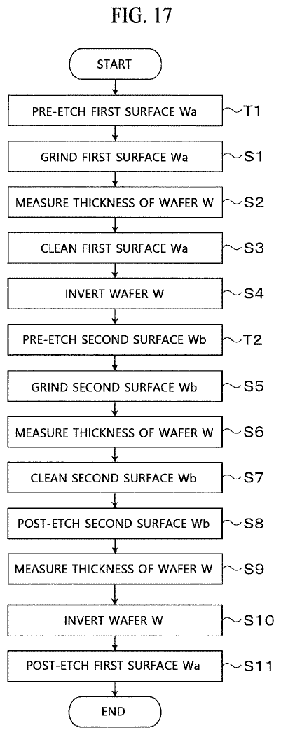

Specifically, the wafer W before being subjected to, for example, the grinding of the first surface Wa (process S1) or the grinding of the second surface Wb (process S5) is transferred to the etching device 50, and the first surface Wa or the second surface Wb is pre-etched in the etching device 50 (process T1 or T2 in FIG. 17). Although a method for the pre-etching is not particularly limited, the surface of the wafer W is flattened at least so as to reduce grinding resistance in the subsequent grinding processings (process S1 or S5). Further, in the process S2, the thickness of the wafer W after being subjected to the pre-etching and the grinding of the first surface Wa may be measured, and conditions on the pre-etching of the second surface Wb in the process T2 may be determined based on the result (thickness distribution and flatness) of the thickness measurement.

Moreover, the various processes S1 to S11 shown in FIG. 17 are performed by the same methods as the various processes S1 to S11 shown in FIG. 5 described above.

At this time, in the grinding processing of the first surface Wa and the second surface Wb in the processes S1 and S5, since the pre-etching of the first surface Wa and the second surface Wb is performed in advance in the processes T1 and T2, a processing load of the grinding can be reduced, so that the grinding processing can be performed appropriately. Specifically, since surface precision of the first surface Wa and the second surface Wb is improved to some extent through the pre-etching, the grinding processing of the first surface Wa and the second surface Wb can be easily carried out.

As a result, the wafer W can be appropriately planarized by the grinding in the processes S1 and S5. Accordingly, in the post-etching (processes S8 and S11) performed afterwards, the etching amount can be reduced, and the surface shape of the wafer W after being etched can be more appropriately controlled.

In addition, in the technique of the present disclosure, the order of the pre-etching, the grinding, the cleaning, the thickness measurement, and the post-etching of first surface Wa and second surface Wb described above is not limited to the example of the above-described exemplary embodiments but may be set as required.

As a specific example, the etching of the first surface Wa (process S11) may be performed prior to the etching of the second surface Wb (process S8). Also, after sequentially performing the pre-etching of the first surface Wa (process T1) and the pre-etching of the second surface Wb (process T2), the various processings (processes S1 to S11) on the first surface Wa and the second surface Wb may be performed.

Further, the above exemplary embodiments have been described for the case where the various processings are performed on both surfaces (first surface Wa and second surface Wb) of the wafer W on which the lapping is performed after being cut out from the ingot with the wire saw or the like. However, the various processings may be performed on one surface of the wafer W.

In addition, the above exemplary embodiments have been described for the case where the various processings are performed on the wafer W on which the lapping is performed after being cut out from the ingot with the wire saw or the like. However, the technique of the present disclosure may be applied to, for example, a post-process in a manufacturing process for a semiconductor device.

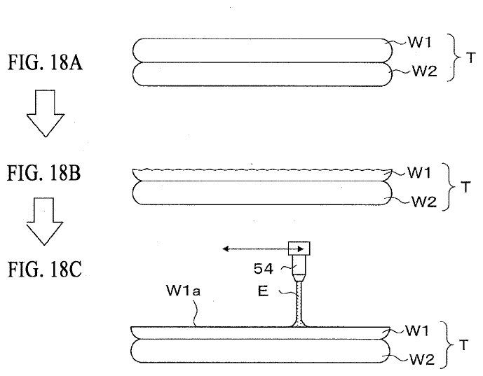

Specifically, in a combined wafer T formed by bonding a first wafer W1 and a second wafer W2 as shown in FIG. 18A, the present disclosure may be also applicable to a case of etching a surface W1a of the first wafer W1 as shown in FIG. 18C after thinning the first wafer W1 as shown in FIG. 18B. Additionally, the method of thinning the first wafer W1 is not particularly limited. For example, the first wafer W1 may be thinned by a grinding processing using a processing device, and may be thinned by separation starting from a modification layer (not shown) formed inside the first wafer W1 by laser processing. In this case, the wafer processing system 1 is equipped with, instead of the processing device 110, a laser processing device (not shown) configured to form the modification layer (not shown).

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
30: Inverting device
31: Inverting device
50: Etching device
51: Etching device
52: Holder
53: Rotating mechanism
54: Nozzle
55: Moving mechanism
110: Processing device
150: Control device
E: Etching liquid
L: Scan width
r: Radius (of substrate)
W: Wafer
Wa: First surface
Wb: Second surface

1. A substrate processing method of processing a substrate, comprising:
thinning a first surface of the substrate; and
etching the first surface by supplying an etching liquid containing at least hydrofluoric acid and nitric acid onto the first surface while rotating the substrate after being thinned and performing a reciprocating movement of an etching liquid supply above the first surface of the substrate to pass a rotation center of the substrate,
wherein the etching of the first surface comprises:
determining a scan width as a distance between return points set at both ends of the reciprocating movement with the rotation center therebetween, and a scan speed at which the etching liquid supply is reciprocated such that a first time taken for the etching liquid supply that has passed the rotation center to pass the rotation center again after turning around at the end of the reciprocating movement becomes shorter than a second time taken for the etching liquid supplied to the rotation center to be removed to an outer peripheral portion of the substrate by a centrifugal force caused by a rotation of the substrate; and
etching the first surface with the determined scan width and the determined scan speed.

2. The substrate processing method of claim 1,
wherein when reciprocating the etching liquid supply, a distance between the rotation center and the return point, which is the end of the reciprocating movement, is equal to or less than a half of a radius of the substrate.

3. The substrate processing method of claim 2,
wherein the distance between the rotation center and the return point is equal to or less than ⅓ of the radius of the substrate.

4. The substrate processing method of claim 1,
wherein a rotation number of the substrate when etching the first surface is set to be of a value that allows the first time to be shorter than the second time.

5. The substrate processing method of claim 1,
wherein when ending the etching of the first surface, the etching liquid supply is moved to a scan-out position between the return point and an outer end of the substrate while discharging the etching liquid, and a discharge of the etching liquid is end at the scan-out position.

6. The substrate processing method of claim 1, further comprising:
acquiring, before the etching of the first surface, a thickness distribution of the first surface by measuring a thickness of the substrate; and
adjusting, before the etching of the first surface, at least one etching condition including the scan width and a rotation number of the substrate based on the acquired thickness distribution.

7. The substrate processing method of claim 1, further comprising:
before the etching of the first surface,
thinning a second surface of the substrate;
etching the second surface of the substrate according to a fixed recipe by supplying the etching liquid from above the second surface, while rotating the substrate;
acquiring, after the etching of the second surface, a thickness distribution of the first surface by measuring a thickness of the substrate; and
determining, based on the acquired thickness distribution of the first surface, at least one etching condition including the scan width and a rotation number of the substrate as an etching condition on the first surface.

8. The substrate processing method of claim 1, further comprising:
acquiring, before the etching of the first surface, a correlation between at least one etching condition including the scan width and a rotation number of the substrate and an etching amount of the substrate;
acquiring, before the etching of the first surface, a thickness distribution of the first surface by measuring a thickness of the substrate; and
determining an etching condition on the first surface based on the acquired correlation and the acquired thickness distribution.

9. A substrate processing system of processing a substrate, comprising:
a thinning device configured to thin a first surface of the substrate;
an etching device configured to etch the first surface after being thinned; and
a control device and a program storage including a program,
wherein the etching device comprises:
a substrate holder configured to hold the substrate;
a rotating mechanism configured to rotate the substrate holder;
an etching liquid supply configured to supply an etching liquid containing at least hydrofluoric acid and nitric acid from above the first surface of the substrate held by the substrate holder; and
a moving mechanism configured to move the etching liquid supply in a horizontal direction, and
wherein the program storage and the program are configured, with the control device, to perform:
a control of, when etching the first surface, performing a reciprocating movement of the etching liquid supply configured to discharge the etching liquid to pass a rotation center of the substrate; and
a control of, by setting a scan width as a distance between return points set at both ends of the reciprocating movement with the rotation center therebetween and a scan speed at which the etching liquid supply is reciprocated, allowing a first time taken for the etching liquid supply that has passed the rotation center to pass the rotation center again after turning around at the end of the reciprocating movement to be shorter than a second time taken for the etching liquid supplied to the rotation center to be removed to an outer peripheral portion of the substrate by a centrifugal force caused by a rotation of the substrate.

10. The substrate processing system of claim 9,
wherein the control device sets a distance between the rotation center and the return point, which is the end of the reciprocating movement, when reciprocating the etching liquid supply to be equal to or less than a half of a radius of the substrate.

11. The substrate processing system of claim 10,
wherein the control device sets the distance between the rotation center and the return point to be equal to or less than ⅓ of the radius of the substrate.

12. The substrate processing system of claim 9,
wherein the control device sets the first time to be shorter than the second time by setting a rotation number of the substrate when etching the first surface.

13. The substrate processing system of claim 9,
wherein the control device performs:
a control of, when ending the etching of the first surface, moving the etching liquid supply to a scan-out position between the return point and an outer end of the substrate while discharging the etching liquid; and
a control of ending a discharge of the etching liquid at the scan-out position.

14. The substrate processing system of claim 9, further comprising:
a thickness measuring device configured to measure a thickness distribution of the substrate,
wherein the control device performs:
a control of, before etching the first surface, acquiring a thickness distribution of the first surface by measuring a thickness of the substrate; and
a control of adjusting at least one etching condition including the scan width and a rotation number of the substrate in the etching device based on the acquired thickness distribution.

15. The substrate processing system of claim 9, further comprising:
a thickness measuring device configured to measure a thickness distribution of the substrate; and
an inverting device configured to invert the first surface of the substrate and a second surface opposite to the first surface in a vertical direction,
wherein before etching the first surface, the control device performs:
a control of thinning the second surface of the substrate;
a control of etching the second surface of the substrate according to a fixed recipe by supplying the etching liquid from above the second surface, while rotating the substrate;
a control of, after etching the second surface, acquiring a thickness distribution of the first surface by measuring a thickness of the substrate; and
a control of determining at least one etching condition including the scan width and a rotation number of the substrate as an etching condition on the first surface based on the acquired thickness distribution of the first surface.

16. The substrate processing system of claim 9, further comprising:
a thickness measuring device configured to measure a thickness distribution of the substrate,
wherein the control device performs:
a control of, before etching the first surface, acquiring a correlation between at least one etching condition including the scan width and a rotation number of the substrate and an etching amount of the substrate; and
a control of, before etching the first surface, acquiring a thickness distribution of the first surface by measuring a thickness of the substrate; and
a control of determining an etching condition on the first surface based on the acquired correlation and the acquired thickness distribution.

17. The substrate processing system of claim 9,
wherein the thinning device comprises a processing device configured to grind the substrate.

18. The substrate processing system of claim 9,
wherein the thinning device comprises a laser radiating device configured to radiate laser light to an inside of the substrate to form a modification layer.

19. The substrate processing system of claim 9,
wherein the substrate as a processing target is a substrate cut from an ingot,
the first surface of the substrate and a second surface opposite to the first surface are processed, and
the substrate processing system further comprises an inverting device configured to invert the first surface and the second surface in a vertical direction.

20. A computer-readable recording medium having stored thereon computer-executable instructions that, in response to execution, cause
a substrate processing system to perform a substrate processing method of processing a substrate,
wherein the substrate processing system comprises:
a thinning device configured to thin a first surface of the substrate;
an etching device configured to etch the first surface after being thinned; and
a control device,
wherein the etching device comprises:
a substrate holder configured to hold the substrate;
a rotating mechanism configured to rotate the substrate holder;
an etching liquid supply configured to supply an etching liquid from above the first surface of the substrate held by the substrate holder; and
a moving mechanism configured to move the etching liquid supply in a horizontal direction, and
wherein the substrate processing method comprises:
thinning the first surface of the substrate; and
etching the first surface by supplying the etching liquid containing at least hydrofluoric acid and nitric acid onto the first surface while rotating the substrate after being thinned and performing a reciprocating movement of the etching liquid supply above the first surface of the substrate to pass a rotation center of the substrate,
wherein the etching of the first surface comprises:
determining a scan width as a distance between return points set at both ends of the reciprocating movement with the rotation center therebetween, and a scan speed at which the etching liquid supply is reciprocated such that a first time taken for the etching liquid supply that has passed the rotation center to pass the rotation center again after turning around at the end of the reciprocating movement becomes shorter than a second time taken for the etching liquid supplied to the rotation center to be removed to an outer peripheral portion of the substrate by a centrifugal force caused by a rotation of the substrate; and
etching the first surface with the determined scan width and the determined scan speed.
